(19) United States
(12) Patent Application Publication
(10) Pub. No.: US 2018/0264997 A1
(43) Pub. Date: Sep. 20, 2018

(54) Screwless Lighthead Fastening System

(71) Applicant: Whelen Engineering Company, Inc., Chester, CT (US)

(72) Inventor: Jon H. Lyons, Haddam, CT (US)

(21) Appl. No.: 15/460,795

(22) Filed: Mar. 16, 2017

(51) Int. Cl. B60Q 1/26; H05K 1/11; H05K 1/18; B60Q 1/52

(52) U.S. Cl. CPC B60Q 1/2696; H05K 1/111; H05K 2201/10121; B60Q 1/52; H05K 1/18

(57) ABSTRACT

A pin is inserted longitudinally into attachment openings of attachment flanges extending rearwardly from an optical element. The flanges extend through a back panel such that the openings are positioned rear of the back panel. When inserted into the openings, each pin flexes inwardly as a leading and trailing guide ramp and a first and second apex pass through the openings. The leading and trailing guide ramps and the first and second apexes then flex outwardly as the first apex transitions to a first seat and/or the second apex transitions to a second seat. There is an outward force of expansion in the frontward to rearward direction when the flanges are positioned on the first and second seats. In this manner, each pin securely attaches the optical element to the back panel.

### BACKGROUND

The present disclosure relates to compact light-generating assemblies referred to as lightheads, and more particularly, to lightheads incorporating LED light sources for use on motor vehicles that are assembled without requiring screws or other similar components that directly fasten elements to one another.

Lightheads for motor vehicles typically include a housing, light source, electrical circuitry, and connections to vehicle power and control devices for actuating the lighthead. A lighthead may be used on various emergency vehicles, such as the warning lights on ambulances, fire engines and law enforcement vehicles. When used as a warning light, a lighthead must comply with various regulations and standards while also being able to function reliably when exposed to potentially damaging environmental conditions, including hot and cold temperature extremes, sunlight, moisture, dust, dirt and various chemicals such as ice melting compounds. Prior art lightheads have employed threaded fasteners to retain housing components to each other and to secure the lighthead to a motor vehicle. In some cases, the same fastener may perform the function of securing housing components to each other and securing the lighthead to a motor vehicle. The fastener may pass through the light emitting (outward-facing) surface of the lighthead, thereby reducing the light-emitting surface area of the lighthead and detracting from the aesthetic appearance of the product. Threaded fasteners may also interfere with automated assembly of the products.

There is a need in the art for lighthead configurations that reduce the number of threaded fasteners needed to assemble a lighthead, while maintaining function, durability and appearance of the product.

### SUMMARY OF THE INVENTION

In the illustrated embodiment, a screwless lighthead fastening system (hereinafter, “system”) is disclosed. The system minimizes, and in some cases even eliminates the usage of fasteners used in fastening a lighthead (or similar accessory) together. To do so, an embodiment of the disclosed system incorporates components and features selected and configured to reduce the use of fasteners. The disclosed structures provide an added advantage over known systems in that they also facilitate automated assembly of the lighthead.

According to aspects of the disclosure, the system reduces the usage of screws by utilizing a plurality of pins to fasten a lighthead together. A typical lighthead comprises a reflector, a printed circuit board a thermally conductive pad and a back panel. The pins cooperate with the components of the lighthead to fasten the lighthead together without needing to be driven directly into any components.

Each pin typically comprises a crown with a substantially flat front surface and a shank extending down longitudinally from the crown to a bottom end. The pin has a substantially flat front surface and an opposing rear surface. The rear surface of each pin includes a leading guide ramp proximate the bottom end and a trailing guide ramp intermediate the leading guide ramp and the crown. The leading guide ramp transitions longitudinally to a first rear apex which transitions to a first seat. The trailing guide ramp transitions longitudinally to a second rear apex which transitions to a second seat. There is a stop intermediate the second seat and the crown.

The reflector includes a plurality of rearward extending attachment flanges. Each flange extends through cooperative slots in the printed circuit board, the thermally conductive pad and the back panel. Each flange defines an attachment opening for receipt of a pin, which can be inserted substantially perpendicular to the flanges. The flanges and the openings are laterally aligned and longitudinally spaced relative to one another.

Each pin is inserted longitudinally into the openings in the flanges. When inserted into the openings, each pin flexes inwardly as the leading and trailing guide ramps and the first and second apexes pass through the openings. The leading and trailing guide ramps and the first and second apexes then flex outwardly as the first apex transitions to the first seat and/or the second apex transitions to the second seat. There is an outward force of expansion in the frontward to rearward direction when the flanges are positioned on the first and second seats. In this manner, each pin securely attaches the reflector to the back panel, with the printed circuit board and thermally conductive pad sandwiched therebetween.

### BRIEF DESCRIPTION OF THE DRAWINGS

Aspects of the preferred embodiment will be described in reference to the drawings, where like numerals reflect like elements:

FIG. 1 is a rear perspective view of a first embodiment of a system according to aspects of the disclosure.

FIG. 2 is a rear exploded view of the system of FIG. 1.

FIG. 3 is a side perspective view of a pin from the system of FIG. 1.

FIG. 4 is a side view of the system of FIG. 1.

FIG. 5 is a side cross-sectional view of the system of FIG. 1.

FIG. 6 is a rear perspective view of a second embodiment of the system according to aspects of the disclosure.

FIG. 7 is a rear perspective view of a third embodiment of the system according to aspects of the disclosure.

### DETAILED DESCRIPTION

Among the benefits and improvements disclosed herein, other objects and advantages of the disclosed embodiments will become apparent from the following wherein like numerals represent like parts throughout the several figures. Detailed embodiments of a screwless lighthead fastening system are disclosed; however, it is to be understood that the disclosed embodiments are merely illustrative of the invention that may be embodied in various forms. In addition, each of the examples given in connection with the various embodiments of the invention which are intended to be illustrative, and not restrictive.

Throughout the specification and claims, the following terms take the meanings explicitly associated herein, unless the context clearly dictates otherwise. The phrases “In some embodiments” and “in some embodiments” as used herein do not necessarily refer to the same embodiment(s), though it may. The phrases “in another embodiment” and “in some other embodiments” as used herein do not necessarily refer to a different embodiment, although it may. Thus, as described below, various embodiments may be readily combined, without departing from the scope or spirit of the invention.

In addition, as used herein, the term “or” is an inclusive “or” operator, and is equivalent to the term “and/or,” unless the context clearly dictates otherwise. The term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.

Further, the terms “substantial,” “substantially,” “similar,” “similarly,” “analogous,” “analogously,” “approximate,” “approximately,” and any combination thereof mean that differences between compared features or characteristics is less than 25% of the respective values/magnitudes in which the compared features or characteristics are measured and/or defined.

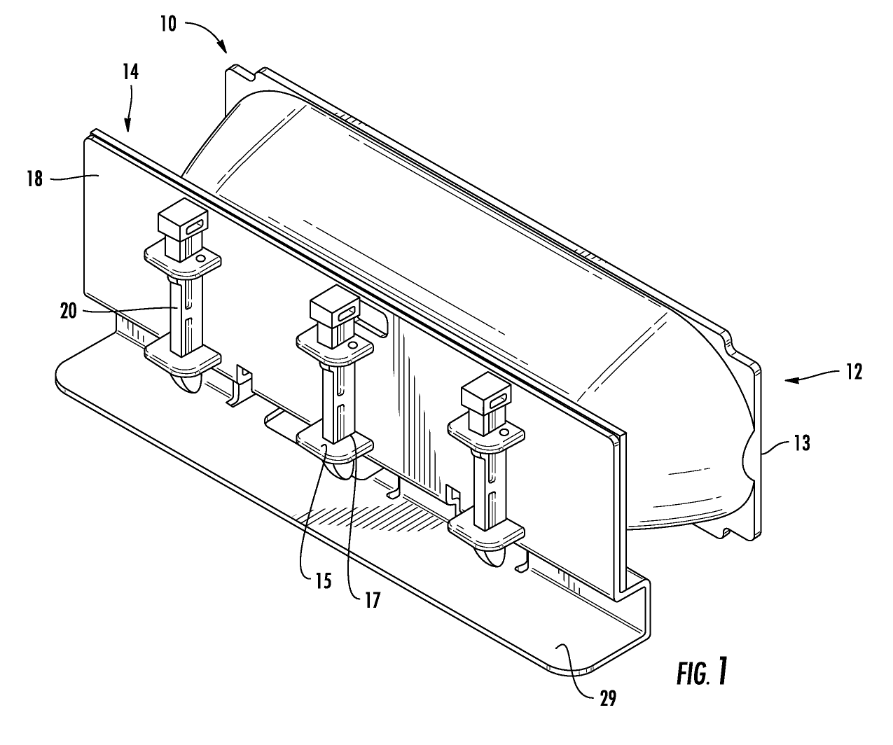

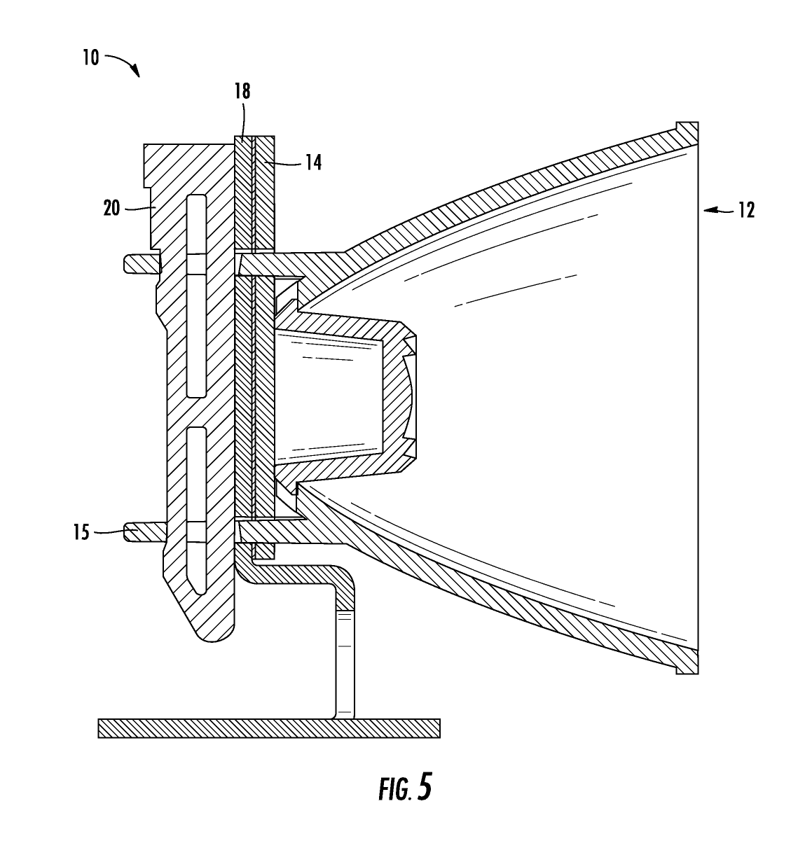

Embodiments of a system according to aspects of the disclosure will now be described with reference to FIGS. 1-7. The system will generally be referred to by the reference numeral 10. Various materials, methods of construction, methods of manufacture, and methods of fastening will be discussed in the context of the disclosed embodiments. Those skilled in the art will recognize known substitutes for the materials, manufacturing methods, and fastening methods, all of which are contemplated as compatible with the disclosed embodiments and are intended to be encompassed by the appended claims.

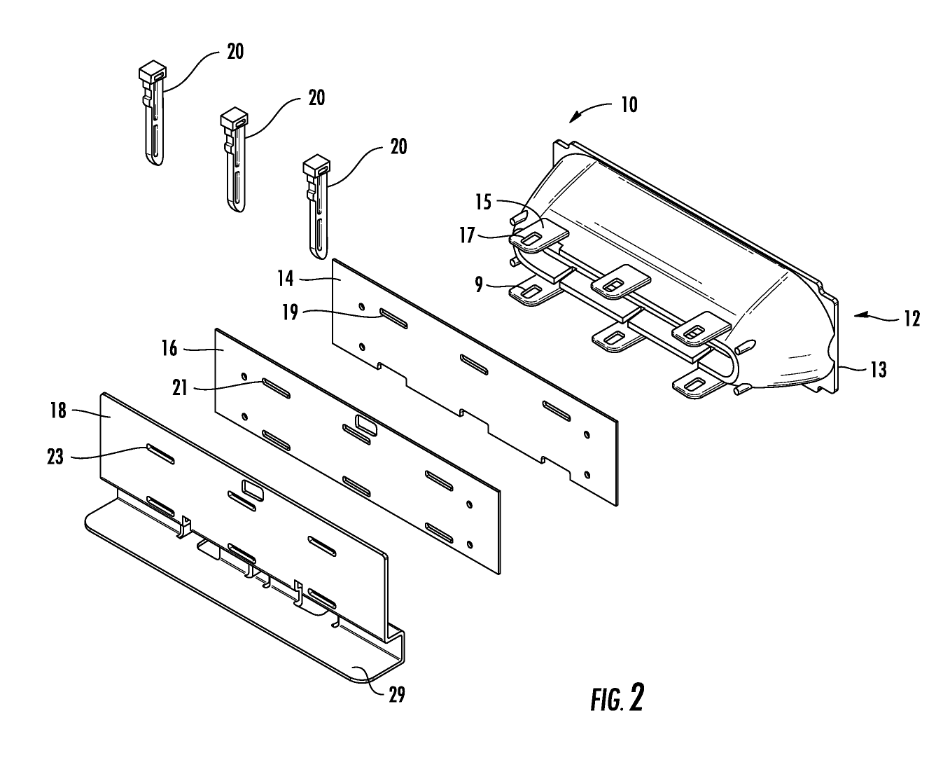

As shown in FIGS. 1 and 2, a first embodiment of the system 10 most generally includes an optical element 12, a printed circuit board 14, a thermally conductive pad 16, a back panel 18 and a set of pins 20. The optical element 12 comprises a reflector 13 having a plurality of rearward extending attachment flanges 15. As shown, the reflector 13 includes a reflecting surface and a lens, but the reflector may comprise any preferred elements for directing light which may be known to those skilled in the art. Each flange 15 defines an attachment opening 17 extending therethrough for receiving the pins 20. As depicted, the first embodiment shown in FIG. 1 includes a plurality of pairs of flanges 15 that are longitudinally spaced from each other with respective openings 17 that are laterally aligned with each other. In another embodiment, the flanges 15 may be shifted such that they are laterally facing with respective longitudinally aligned openings 17.

The printed circuit board 14 is substantially flat and includes all of the appropriate electronics for the optical element 12, such as driver circuits and LEDs. In the first disclosed embodiment, the thermally conductive pad 16 has a flat front and rear surface and is made of a heat conductive material. The back panel 18 is substantially flat and includes a lower platform 29 that extends perpendicularly. The printed circuit board 14, the thermally conductive pad 16 and the back panel 18 each define a series of slots 19, 21 and 23, respectively, that accommodate the flanges 15. Each slot (19, 21, 23) is laterally aligned and longitudinally spaced. Each slot (19, 21, 23) is oriented in a substantially identical position within respective planes such that each slot (19, 21, 23) receives a flange 15 from the optical element 12. When the printed circuit board, the thermally conductive pad and the back panel (14, 16, 18) are placed together surface-to-surface, respective slots (19, 21, 23) define a series of channels for receiving the flanges 15. In the first disclosed embodiment, two rows of slots (19, 21, 23) are depicted, but there may be more slots (19, 21, 23) as needed in an alternative embodiment of the system 10 to accommodate more flanges 15.

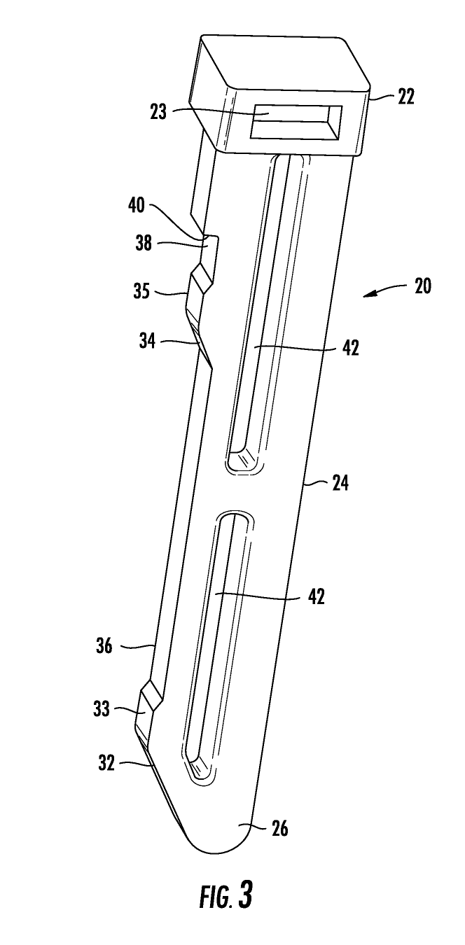

As shown in FIG. 3, each pin 20 includes a shank 24 extending from a crown 22. Preferred embodiments of the pins 20 are constructed of glass-filled nylon, but other materials having strength and flexibility are compatible with the disclosed system 10. In the first disclosed embodiment, the crown 22 is fit with side grooves 23 for assisting in automation and manufacturing. The shank 24 extends downward longitudinally from the crown 22 to a bottom end 26. As shown, the shank 24 and the crown 22 form a single flat front surface and a rear surface with varying contours. Each pin 20 is sized and shaped to forcibly wedge through a pair of the longitudinally spaced openings 17, with the front surface tightly abutting the surface of the back panel 18 to maintain the printed circuit board, the thermally conductive pad and the back panel (14, 16, 18) in a tight surface-to-surface attachment.

In the first disclosed embodiment, the front surface of the pin 20 is substantially planar and spans the entire length from the bottom end 26 to a top of the crown. The rear surface of the pin 20 includes a leading guide ramp 32 proximate the bottom end 26. The rear surface also includes a trailing guide ramp 34 intermediate the leading guide ramp 32 and the crown 22. The leading guide ramp 32 transitions longitudinally to a first rear apex 33 which transitions to a first seat 36. Similarly, the trailing guide ramp 34 transitions longitudinally in the same manner to a second rear apex 35 and then to a second seat 38. Each apex 33, 35 may include a flat or nearly flat surface or plateau. A stop 40 may be included longitudinally intermediate the second seat 38 and the crown 22. The shank 24 includes a pair of narrow middle slits 42 that extend longitudinally through the body of the shank.

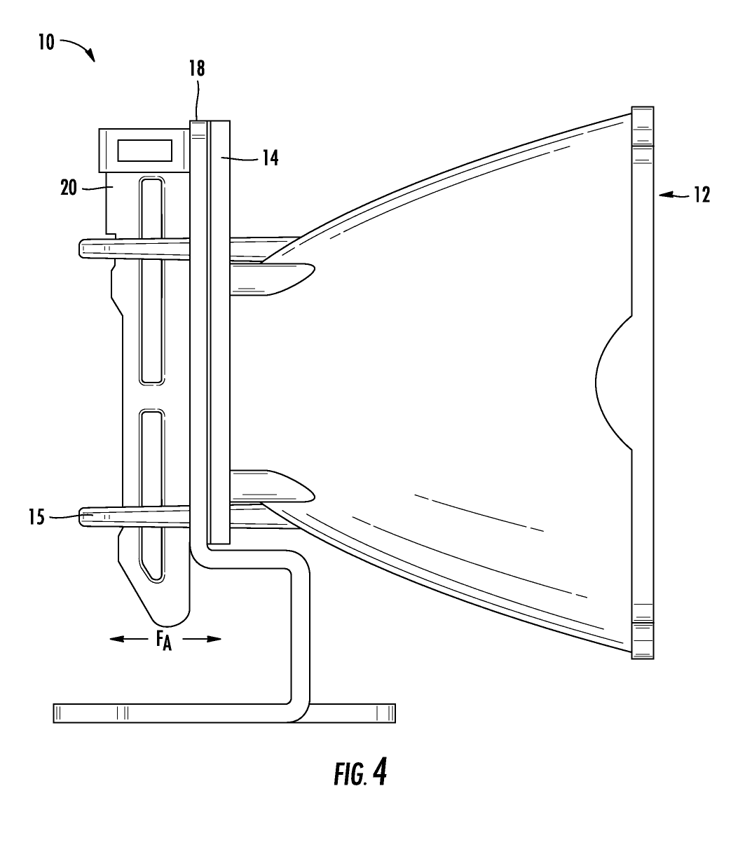

Each pin 20 is inserted longitudinally (as shown in FIG. 1) or laterally (not depicted), depending on the arrangement of the flange 15 and the slots (19, 21, 23). The middle slits 42 are aligned with the points at which the ramps 32, 34, the apexes 33, 35 and the seats 36, 38 are in contact the flanges 15 when each pin 20 is inserted through each opening 17. The configuration of the middle slits 42 allows for inward flexure of the shank 24 as the leading guide ramp 32 and first rear apex 33 are forcibly wedged through the openings 17 and outward return flexure as the corresponding trailing guide ramp 34 and second rear apex 35 transition to the second seat 38. The outward return flexure of the pin 20 applies an outward force F_{A} between the back panel 18 and an inner surface 9 of each opening 17. Reference character F_{A} in FIG. 4 generally depicts the directional nature of the outward flexure of each pin 20 in an installed configuration.

As shown in FIGS. 3 and 4, the printed circuit board, the thermally conductive pad and the back panel (14, 16, 18) are placed together in surface-to-surface abutment with respective slots (19, 21, 23) aligned to define a channel. The optical element 12 is positioned in front of the printed circuit board 14 with each flange 15 extending through a channel such that each opening 17 is positioned rear of the back panel 18. When the system 10 is assembled with each pin 20 wedged within each opening 17, the printed circuit board 14 and the thermally conductive pad 16 are sandwiched tightly between the back panel 18 and the optical element 12.

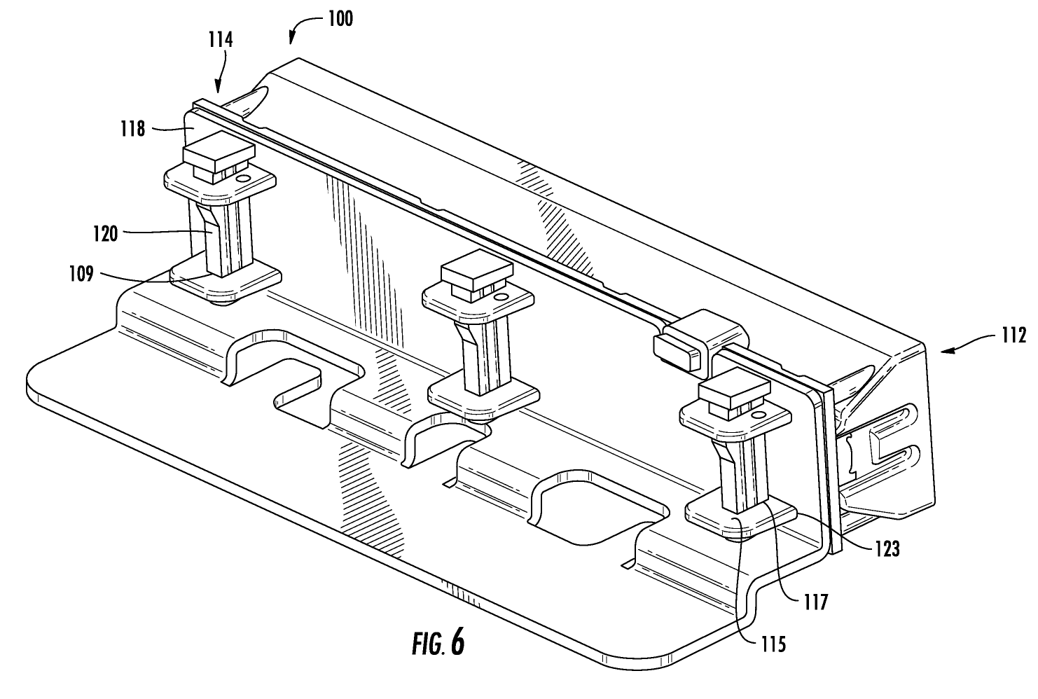

FIG. 6 shows a second embodiment of the system 10. In the second disclosed embodiment, the system 100 includes a shortened optical element 112, printed circuit board 114, thermally conductive pad 116 and back panel 118. As in the first embodiment, the narrow optical element 112 includes a plurality of rearward attachment flanges 115 defining attachment openings 117. The printed circuit board, thermally conductive pad (not depicted) and the back panel (114, 118) each define a series of slots. The printed circuit board, thermally conductive pad (not depicted) and the back panel (114, 118) sandwich together in a surface-to-surface arrangement such that respective slots 123 align to form a series of channels for receipt of the flanges 115. As in the first disclosed embodiment, the flanges 115 extend rearward of the back panel 118 such that the openings 117 are positioned rear of the back panel 118 and a shortened pin 120 is forcibly wedged through the openings 117. The shortened pin 120 abuts the back panel 118 and applies the outward force F_{A} between the back panel 118 and an inner surface 109 of the openings 117, holding the system 100 in a tight engagement.

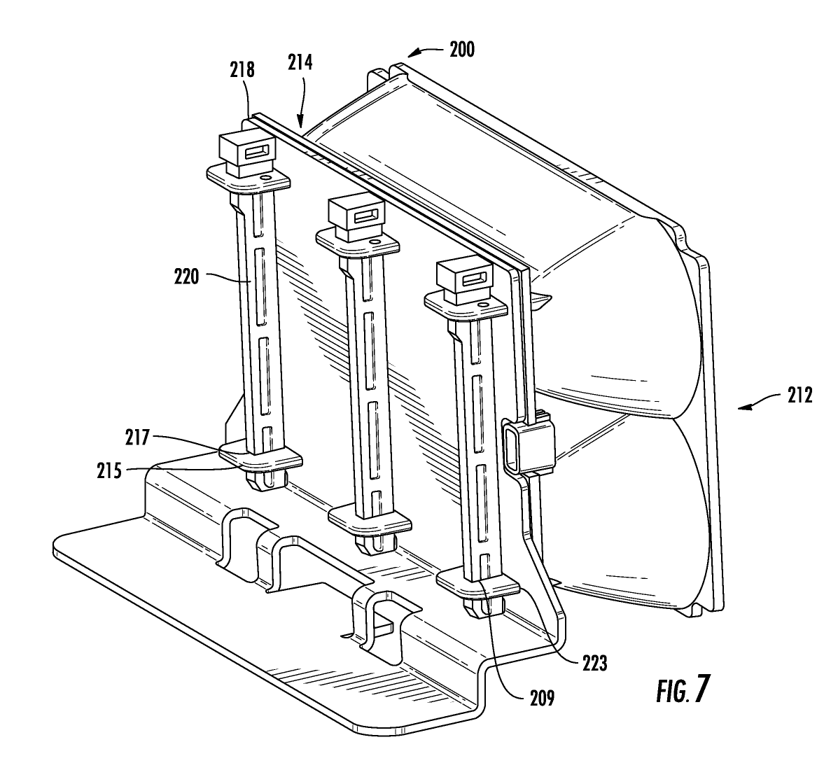

FIG. 7 shows a third embodiment of the system 10. In the third disclosed embodiment, the system 200 includes an elongated optical element 212, printed circuit board 214, thermally conductive pad 216 and back panel 218. As in the first and second embodiments, the elongated optical element 212 includes a plurality of rearward attachment flanges 215 defining attachment openings 217. The printed circuit board, thermally conductive pad (not depicted) and the back panel (214, 218) each define a series of slots (223). The printed circuit board, thermally conductive pad (not depicted) and the back panel (214, 218) sandwich together in a surface-to-surface arrangement such that respective slots (223) align to form a series of channels for receipt of the flanges 215. As in the first disclosed embodiment, the flanges 215 extend rearward of the back panel 218 such that the openings 217 are positioned rear of the back panel 218 and an elongated pin 220 is forcibly wedged through the openings 217. The elongated pin 220 abuts the back panel 218 and applies the outward force F_{A} between the back panel 218 and an inner surface 209 of the openings 217, holding the system 200 in a tight engagement.

The tight engagement established by the outward force F_{A} provided by the pin 20 allows the system 10 to be screwless and secure. Though the use in the disclosed embodiments is primarily for a lighthead 12, the system 10 can be employed in a variety of ways and/or on any device where there is a sandwiched, surface-to-surface arrangement of parts.

While a preferred embodiment of the disclosed screwless lighthead fastening system has been set forth for purposes of illustration, the foregoing description should not be deemed a limitation of the invention. Accordingly, various modifications, adaptations and alternatives may occur to one skilled in the art without departing from the spirit of the disclosure and scope of the claimed coverage.

1-6. (canceled)

7. A lighthead assembly comprising:
an optical element having a plurality of attachment flanges defining attachment openings;
a back panel defining a plurality of slots for receiving the flanges of the optical element;
a pin for inserting into the openings;
a printed circuit board and a thermally conductive pad each defining a plurality of slots, the printed circuit board and the thermally conductive pad sandwiched between the optical element and the back panel; wherein,
the flanges of the optical element extend through the slots in the printed circuit board, the thermally conductive pad and the back panel, the openings positioned rear of the back panel, and the pin is inserted into the openings of the flanges to provide outward expansion forces between the flanges and the back panel to hold the optical element in tight engagement with the back panel and the printed circuit board and the thermally conductive pad therebetween.

8. The lighting assembly of claim 7, at least two pairs of flanges are laterally aligned and longitudinally spaced from each other.

9. The lighting assembly of claim 7, wherein an inward flexure of the pin allows the pin to forcibly wedge through the openings and an outward flexure of the pin allows the pin to apply a force on an inner surface of the opening.

10. The lighting assembly of claim 7, wherein the pin includes a substantially flat front surface and a rear surface of varying contours.

11. The lighting assembly of claim 10, the rear surface of the pin includes a leading guide ramp proximate a bottom end and a trailing guide ramp intermediate the leading guide ramp and a crown, the leading guide ramp transitioning longitudinally to a first rear apex which transitions to a first seat, the trailing guide ramp transitioning longitudinally to a second rear apex which transitions to a second seat and a stop intermediate the second seat and the crown.

12. The lighting assembly of claim 10, wherein the rear panel has a substantially flat rear surface and the substantially flat front surface of the pin tightly abuts the rear surface of the back panel in a surface-to-surface abutment when the pin is inserted into the opening in a flange.

13. A method of assembling a lighting system, comprising:
(a) providing an optical element having a plurality of attachment flanges defining attachment openings;
(b) inserting each flange of the optical element rearwardly through a slot in a rigid substantially flat back panel such that the openings in the flanges are exposed rearward of the back panel; and
(c) inserting a pin into each opening of the flanges, wherein the pin exerts expansion forces against an inner surface of the openings and back panel to hold the optical element in tight engagement against the back panel.

14. The method of claim 13, comprising the steps of:
providing a printed circuit board and a thermally conductive pad, each defining a plurality of slots;
aligning the printed circuit board, thermally conductive pad and rear panel with each other with the respective slots in alignment before step (b), wherein
step (b) includes inserting each flange through the slots in the printed circuit board and thermally conductive pad, and inserting the pins provides a tight mating with the printed circuit board and thermally conductive pad sandwiched between the rear panel and optical element.

15. The method of claim 13, wherein insertion of a pin into an opening in a flange causes inward flexure of the pin and forcible wedging of the pin through the opening, followed by outward return flexure of the pin resulting in a force F_{A} on an inner surface of the opening and a rear surface of the back panel.

16. The method of claim 13, wherein each pin is inserted substantially longitudinally and perpendicular to the flange.

17. The method of claim 13, wherein each pin is inserted into an opening in a flange via an automated tool.

18. The method of claim 13, wherein each pin has a substantially flat front surface that tightly abuts a rear surface of the back panel in a surface-to-surface abutment when the pin is inserted.

19. A method of assembling a lighting system, comprising:
(a) providing an optical element having a plurality of attachment flanges defining attachment openings;
(b) inserting each flange of the optical element rearwardly through a slot in a rigid substantially flat back panel such that the openings in the flanges are exposed rearward of the back panel; and
(c) inserting a pin into each opening of the flanges, wherein inserting the pin causes inward flexure of the pin and forcible wedging of the pin through the opening, followed by outward return flexure of the pin resulting in a force F_{A} on an inner surface of the opening and a rear surface of the back panel to hold the optical element in tight engagement against the back panel.

20. The method of claim 19, wherein each pin is inserted substantially longitudinally and perpendicular to the flange.

21. The method of claim 19, wherein each pin is inserted into an opening in a flange via an automated tool.

22. The method of claim 19, wherein each pin has a substantially flat front surface that tightly abuts a rear surface of the back panel in a surface-to-surface abutment when the pin is inserted.
